(19) United States
(12) Patent Application Publication
(10) Pub. No.: US 2005/0207133 A1
(43) Pub. Date: Sep. 22, 2005

(54) Embedded power management control circuit

(76) Inventors: Mark Pavier, Felbridge (GB); Tim Sammon, Hove (GB)

Correspondence Address: Attention: Lawrence A. Hoffman;OSTROLENK, FABER, GERB & SOFFEN, 1180 Avenue of the Americas, New York, NY, 10036-8403, US

(21) Appl. No.: 11/078,807

(22) Filed: Mar. 11, 2005

Related U.S. Application Data
(60) Provisional application No. 60/552,143, filed on Mar. 11, 2004.

(51) Int. Cl. G06F 1/16

(52) U.S. Cl. 361/761

(57) ABSTRACT

A peripheral electronic system for an electronic device including a motherboard having multiple individual electrically connected vertically stacked modules, at least one of which is a circuit board assembly including active and/or passive electronic components embedded therein with the components being electrically connected by conductive traces to provide desired operating function. The peripheral electronic system further includes an electrical connector array on an exposed surface of the composite structure to provide electrical connections between the peripheral electronic system and the motherboard.

### RELATED APPLICATION

The present application is based on and claims the benefit of U.S. Provisional Application No. 60/552,143, filed on Mar. 11, 2004, entitled EMBEDDED POWER MANAGEMENT CONTROL CIRCUIT, the entire contents of which are expressly incorporated herein by reference.

### FIELD OF THE INVENTION

The present invention relates broadly to compact assemblies of semiconductor electronic systems, and more particularly, to such systems in which compactness is achieved by embedding active and passive electronic devices in circuit boards of constituent subsystems which are then assembled in vertical stacks. One specific application of this invention is to power management control circuit modules which can be assembled with power converters for use in small, portable electronic devices. Alternatively, the embedded power management control circuit may be modified for use in circuits containing a power transistor device and controller. Such applications include audio class D circuits, half bridge and full bridge motor control applications and lighting circuits. For the purposes hereof, the term “embedded” is to be understood to mean buried within a substrate or carrier.

### BACKGROUND OF THE INVENTION

Portable electronic devices, such as cell phones and computers, need efficient power management control circuits that occupy little volume. Such circuits may include power transistors, integrated circuits, resistors, capacitors, inductors, diodes, wiring, sensors and comparators.

Conventional assembly of such power control circuits on printed circuit boards consume excessive volume and area. As functionality increases, the demand for volume reduction becomes increasingly important.

Use of embedded passive devices, such as resistors and capacitors, is known. By embedding active and/or passive devices in a circuit board, valuable real estate on the surface of the circuit board is conserved for active semiconductor devices.

### BRIEF SUMMARY OF THE INVENTION

An embedded power management control circuit according to one embodiment of the present invention comprises a control board module assembled with an integrated circuit power converter in a vertical stack for attachment to a motherboard of a handheld device. The control board module, including a power transistor such as a field effect transistor (FET), and/or an integrated circuit mounted below the power supply integrated circuit, saving space on the motherboard of the device. Passive devices (e.g., resistors, capacitors and inductors) may also be embedded in the control board module saving additional real estate on the motherboard of the device. For example a circuit containing a MOSFET, IC and passive components may be embedded within a carrier having a land grid array pad arrangement that may be soldered to a mother board. A heatsink may be attached to the assembly in order to increase the heat dissipation to the ambient surrounding the embedded components.

One object of the present invention is to package a peripheral electronic system for a small portable electronic apparatus in a module which exhibits a small footprint and small volume.

A more particular object of the invention is to provide such a compact peripheral electronic system which can serve as a power converter and power control module for convenient attachment to a motherboard in a small electronic device such as a cell phone or the like.

According to a first aspect of the invention, a peripheral electronic system for an electronic device having a motherboard includes a composite structure with a plurality of individual electrically connected vertically stacked modules, at least one of which is comprised of a circuit board assembly including active and/or passive electronic components embedded therein with the components being electrically connected by conductive traces to provide desired operating function, and further includes an electrical connector array on an exposed surface of the composite structure adapted to provide electrical connections between the peripheral electronic system and the motherboard.

According to a second aspect of the invention, an electronic device includes a peripheral electronic system according to the first aspect, and also a motherboard, with the motherboard and the peripheral electronic system connected together electrically by the electrical connector array.

According to a third aspect of the invention, a method of assembling a peripheral electronic system for an electronic device including a motherboard and the peripheral electronic system, the method comprising the steps of fabricating a first module in the form of a circuit board including a first group of electronic components embedded therein and electrically interconnected by embedded conductive traces to provide a first part of the functionality of the peripheral electronic system, then encapsulating the circuit board while leaving an exposed electrical connecting structure, fabricating a second module including a second group of electronic components embedded therein which are electrically connected to provide the second part of the functionality of the peripheral electronic system, then encapsulating the second module while leaving an exposed second electrical connecting structure, assembling the first and second encapsulated module in a vertical stack with the first sand second electrical connection structures providing electrical connection between the first and second modules; and providing a third electrical connecting structure on an exposed surface of one of the vertically stacked modules, which is adapted for electrically connecting the assembled modules to the motherboard.

According to a fifth aspect of the invention, a method assembling an electronic device including a motherboard and a peripheral electronic system, comprises assembling the peripheral electronic subsystem according to the method of the fourth aspect of the invention, and electrically attaching the third connecting structure on the peripheral electronic system to the motherboard.

### BRIEF DESCRIPTION OF THE DRAWINGS

FIG. 1 illustrates a cross-sectional view of one embodiment of the present invention.

FIGS. 2A-2F illustrate cross-sectional views showing a process for embedding active semiconductor devices.

FIGS. 3A-3I illustrate a process for embedding passive devices.

FIG. 4 shows a circuit diagram for one embodiment of the present invention.

FIG. 5 shows a circuit board assembly according to the invention with an attached heat sink.

FIGS. 6A-6C show contact pattern layers for one embodiment of the present invention.

### DETAILED DESCRIPTION OF THE INVENTION

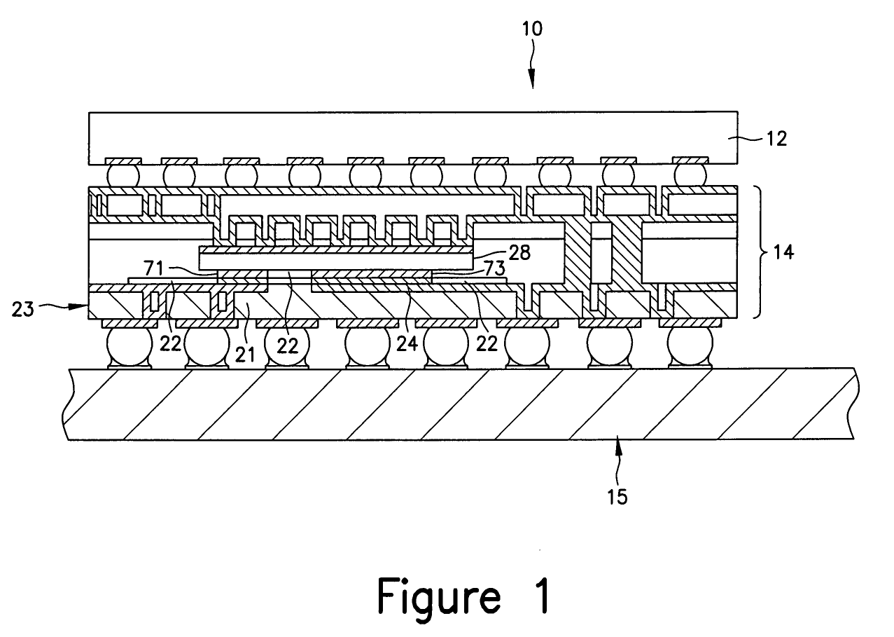

An embedded power management point of load delivery control circuit assembly 10 is illustrated in FIG. 1. A control board 14 is interposed between a power integrated circuit 12, such as a d-c to d-c power converter, and a motherboard 15 of an electronic device. For example, the electronic device may be a small cellular phone, which requires optimal use of the printed circuit board real estate in order to reduce the size of the device.

The power IC 12 may contain control circuitry for a synchronous buck converter, a control MOSFET, a synchronous MOSFET, over-current/over-voltage protection and over-temperature protection. Alternatively, power IC 12 maybe a power supply module of any other suitable or desired architecture and construction. Embedded passive devices, such as resistors, capacitors and inductors may be added in layers appended to the die surface. Power transistors such as field effect transistors (FETs) are embedded in control board 14 interposed between the power IC and the motherboard.

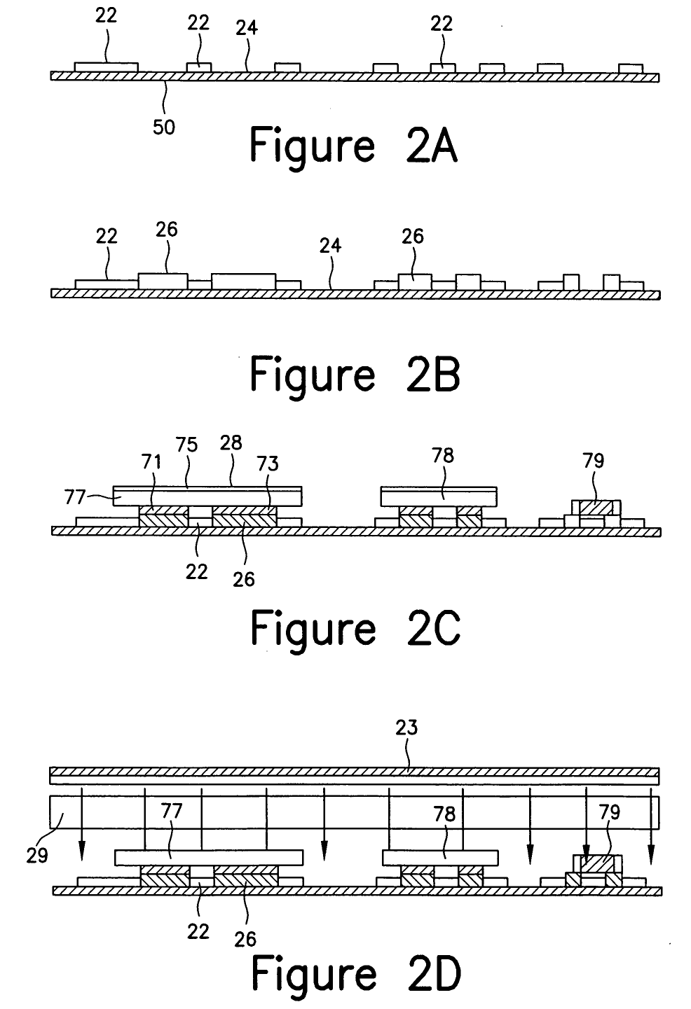

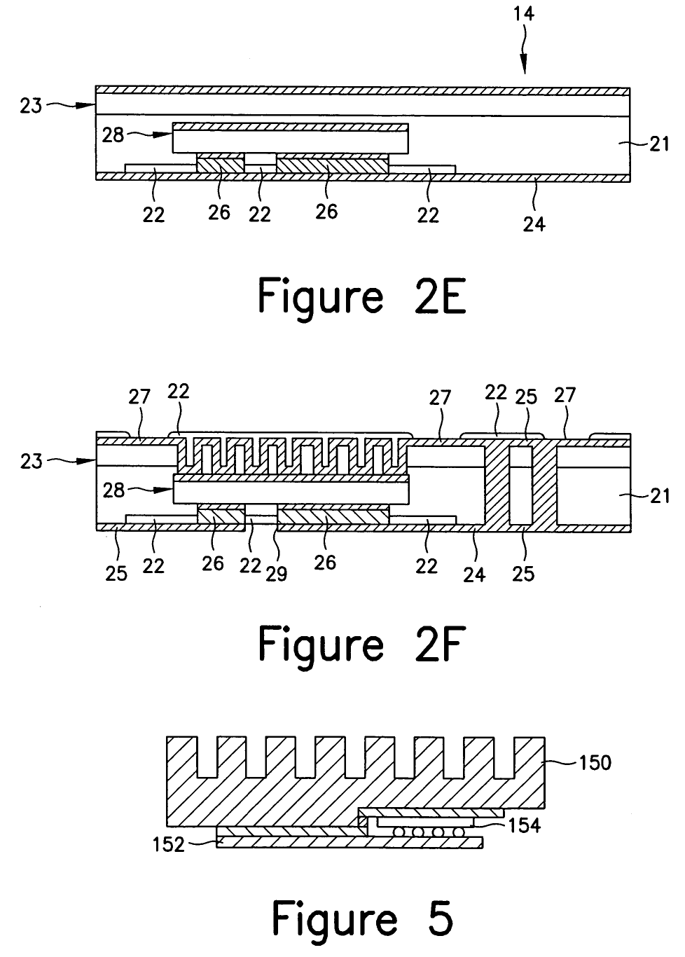

A suitable process for assembling control board 14 with embedded active semiconductor devices is shown in FIGS. 2A-2F, but it should be understood that the invention is not limited to the illustrated process. In FIG. 2A, an electrically insulating mask layer 22 is applied to a conductive layer 24 which may be conductive surface on a insulating layer 21 of a conventional ball grid array 23 (see FIG. 1) or a land grid array style package. Conductive layer 24 may alternatively be a copper foil of a direct bonded copper (DBC) element, the upper conductive component of an insulated metal substrate (EMS) or a copper foil element used in a printed wiring board. Alternatively the conductive layer may form part of a complex leadframe assembly such as those used in power electronics applications.

As the next step, as shown in FIG. 2B, a conductive adhesive 26 is applied to at least a portion of the exposed conductive surface 24 as defined by a mask layer 22 such as a conventional solder mask. The conductive adhesive 26 may be a solder or an electrically conductive epoxy die attach adhesive, or any other suitable or desired material, applied, for example, by screen printing.

In the next step, as shown in FIG. 2C, an active semiconductor device 28, such as a FET or IC, is mounted such that electrical contact is made between electrodes 71, 73 on one major surface of the semiconductor device and the conductive adhesive 26. For example, the semiconductor device may be connected by contact pads on its surface. This surface may contain a solderable metal or metal containing adhesive, an array of solder bumps or an array of metallic or polymeric studs, or any other suitable or desired structure. The other major surface 75 is a metallization on the body of die 77. For a power device, this may be the back metallization, for an IC, this can be metallization on the electrodes. Likewise , other semiconductor and passive devices such as diodes, MESFETs or IGBT's, capacitors, resistors or inductors may be mounted and spaced in relationship to device 28. For example, as shown in FIG. 8A-8D a resistor 79 and a second MOSFET 78 device may be placed on the adhesive 26 deposited on the copper foil 24.

Then, semiconductor device 28 and spaced devices 78 and 79 may be embedded in an electrically insulating encapsulant 21, such as a pre-preg adhesive bonding ply or similar adhesive film and a laminated core 23 formed of a dielectric backed copper foil or simply a copper foil may be applied, as shown in FIG. 2D. The resulting control board 14 module is illustrated in FIGS. 1 and 2E. Conductive layer 24 may be etched at 29 to define contacts and wire traces as shown in FIGS. 1 and 2F. Wire traces 25 and pads 27 may be incorporated in laminated core 23 either before or after incorporation in control board 14 by any suitable or desired process, such as by drilling holes, followed by metallization and patterning.

To add further layers of passive and/or other active semiconductor devices to either surface of the control board, the fabrication process described above in connection with FIGS. 2A-2F is repeated, with connections between layers made by metallized vias, as described in more detail below.

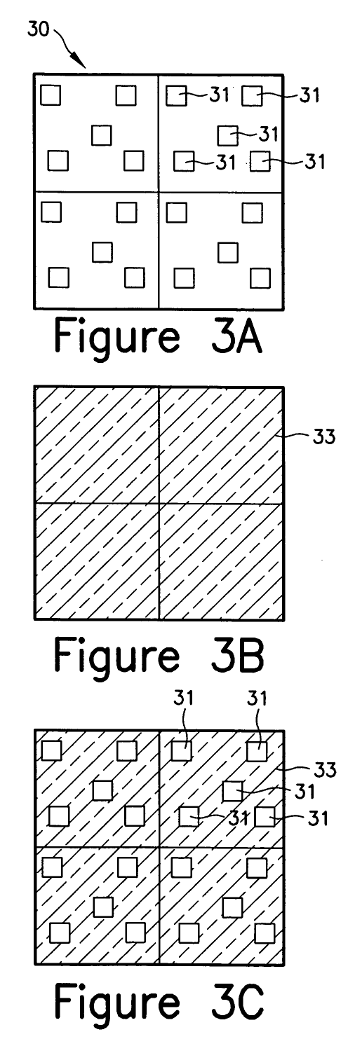

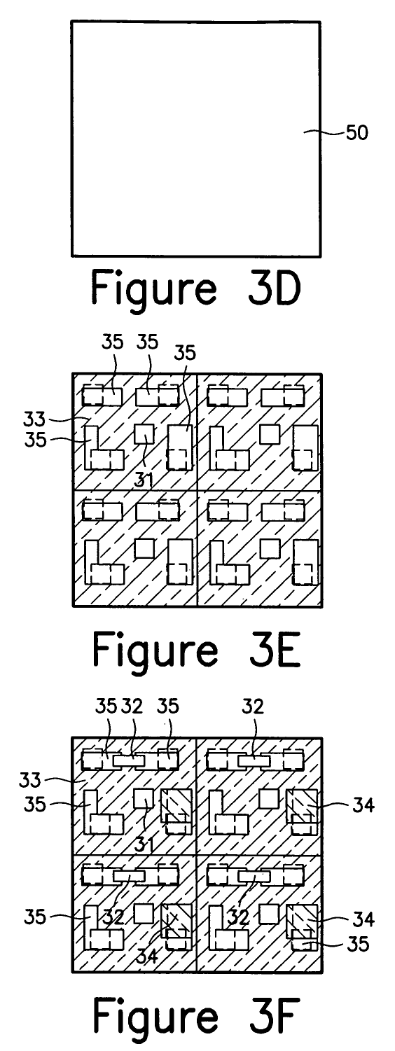

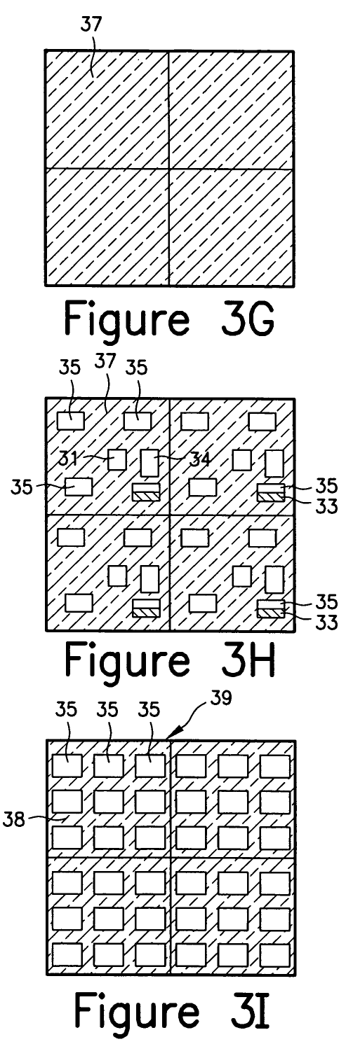

FIGS. 3A-3I illustrate an example of a process for embedding passive devices in a structure such as control board 14. FIG. 3A illustrates an embedded IC device 30, for example, a control IC, with contact pads 31 on one of its surfaces. In FIG. 3B, a passivation layer 33 is shown applied over contact pads 31. A portion of the passivation layer 33 is then removed, such as by etching, to expose at least some of the contact pads 31 (see FIG. 3C). Next a metallization layer 50, for example in the form of electroplated copper, is applied to the surface of IC 30 over contact pads 31, as shown in FIGS. 3D, and patterned by etching, to produce conductive pattern tracks 35 as shown in FIG. 3E. Other suitable processes for creating the pattern tracks shown in FIG. 3E include vapor deposition, sputtering or screen printing.

Alternatively, a nonmetallic, conductive pattern may be used in place of the patterned metallization layer. For example, an electrically conductive paste may be printed on the surface to form the desired contact pattern 35 and subsequently cured.

Next, passive components 32, 34 may be deposited on or between the tracks of contact pattern 35, such as by screen printing a resistive paste 32 or a dielectric paste 34 for resistors and capacitors, respectively. Similarly an inductor may be formed by a spiral pattern in copper layer 50.

An electrically insulating material having a high dielectric constant, such as a polymer/ceramic composite is printed on the surface of a first electrically conductive contact and a second electrically conductive contact is positioned opposite of the first electrically conductive contact sandwiching the electrically insulating material between the two conductive contacts.

In FIG. 3G, a second passivation layer 37 is applied, and portions of the passivation are removed to reveal pattern tracks 35 and contacts 31 for the underlying passive components 32 and 34, and IC 30. Subsequent steps of plating and etching and/or printing may be used to build up additional layers of passive electronic components as required. Additional layers of passivation and conductive traces may be applied to build up and form a pad grid array 39 having electrically conducting contact pads 36 separated by an insulating grid 38, as shown in FIG. 3I. This pad grid array 39 may be used with balls of solder in a conventional ball grid array for connecting the integrated circuit 30 and passive components 32, 34 with another circuit board or a semiconductor device, as shown in FIG. 1, for example.

The resulting three-dimensional structure of active and passive components, when electrically connected to an external circuit such as motherboard 15, can be used to provide embedded power management control with minimum utilization of motherboard area.

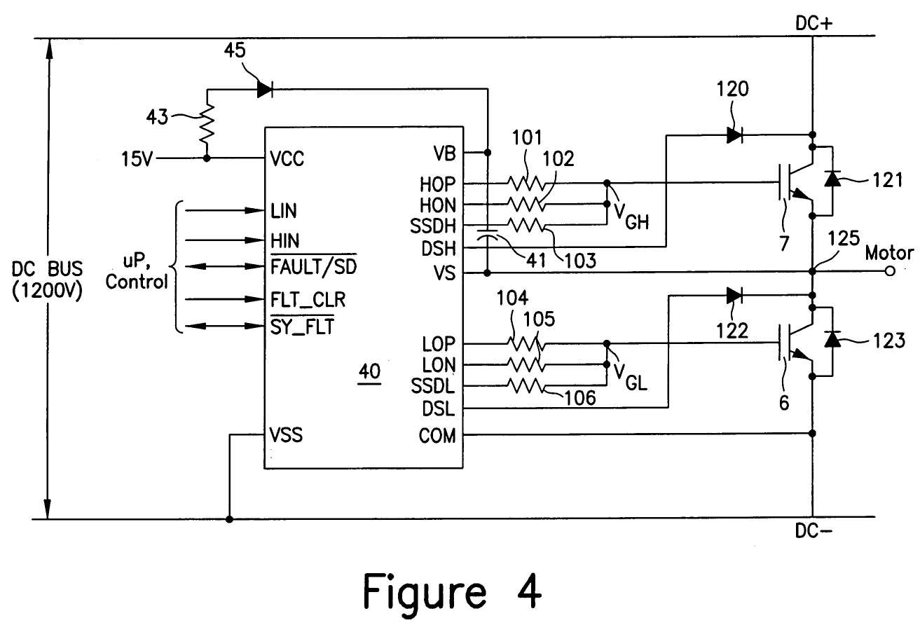

As an example of an embedded semiconductor device constructed according to the principles of this invention, FIG. 4 shows a circuit diagram of a control board 14 including an IC 40 which functions as a half-bridge gate driver, and one or more embedded MOSFET or IGBT devices 6 and 7 of which control the current flow between the positive and negative DC rails (DC+ and DC− or GND) and the output node 125 connected to a motor. Also included are an embedded bootstrap capacitor 41, a bootstrap resistor 43 and a diode 45 which forms part of the bootstrap circuit required to drive the high side MOSFET 121, and embedded resistors 101-106 which control the current into and out of the gates of the power devices 6 and 7. It should be noted that the circuit diagram is intended to be a generic one that represents a typical half bridge. Resistors 101 through 106 may not be present on all driver circuits. One terminal of each of the resistors 101 through 103 are connected to the gate of the high side device 7. The opposite terminals of each resistor are connected to individual pins on the control IC 40. Resistors 104 through 106 are connected in a similar configuration but to the gate of the low side device 6. Bootstrap capacitor 41, bootstrap resistor 43 and diode 45 are electrically connected to the half-bridge gate driver integrated circuit 40 by integrated wire traces, contact pads and ball grid arrays.

In one application, by connecting embedded bootstrap capacitor 41 in parallel with an electrolytic tank bootstrap capacitor (not shown), capacitor 41 can act as a fast charge tank for the gate charge only and the electrolytic tank capacitor keeps the voltage ripple (ΔV_{BS}) across the parallel bootstrap capacitors within acceptable limits. Alternatively, embedded bootstrap capacitors 41 may be used without an electrolytic tank capacitor if the limitations of using only ceramic or polymer/ceramic capacitors as the bootstrap capacitor 41 are acceptable.

Selecting the value of bootstrap capacitor 41 is known to limit duty-cycle and on-time of the power MOSFETs, because the charge on the bootstrap capacitor 41 must be refreshed periodically. Specific sizing of bootstrap capacitors 41 is known in the art, as described in co-pending U.S. patent application Ser. No. 10/696,711, filed Oct. 29, 2003, now U.S. Pat. No. 6,859,087, issued Feb. 22, 2005. The capacitance size of an embedded bootstrap capacitor 41 is defined by the area, thickness and dielectric constant of the insulating layer, for example. Thus, the embedded bootstrap capacitor 41 may be sized and the dielectric constant selected such that the embedded capacitor 41 or capacitors meet the requirements for a bootstrap capacitor 41 of the power management control device 10.

Wiring traces and wiring contacts may be provided by the embedding process described above such that embedded capacitor 41 is electrically coupled, along with as a bootstrap capacitor for an integrated power management control circuit including completing the bootstrap circuit, as shown in FIG. 4.

The MOSFETs 6, 7 of FIG. 4 may be any power transistor. For example, an insulating gate bipolar transistor IGBT, such as IRGP30B120K(D), and IRG4PH30K(D) manufactured by International Rectifier Corporation may be used. Preferably, the MOSFETs embedded in the control boards are a Flip FET or FETKY devices which may be mounted using automated pick and place equipment. Alternatively, these devices may be any MOSFET with a suitable surface contact that may be attached to tracking layer 24.

A heat sink (150) may be attached to one or more surfaces of control board 14. Preferably, the thermal resistance between the heat sink and the heat-generating devices such as diodes 120-123 and power transistors 6, 7 is reduced by making thermal pathways to the embedded heat-generating devices. For example, thermal pathways may be provided by placing heat-generating devices near one of the surfaces of the control board, by using thermally conductive materials to conduct heat from the surface of the heat-generating device or both. The heat sink may be used for both embedded and non-embedded heat-generating devices. FIG. 5 illustrates a heat sink 150 sandwiched between a control board 152 and another non-embedded device 154.

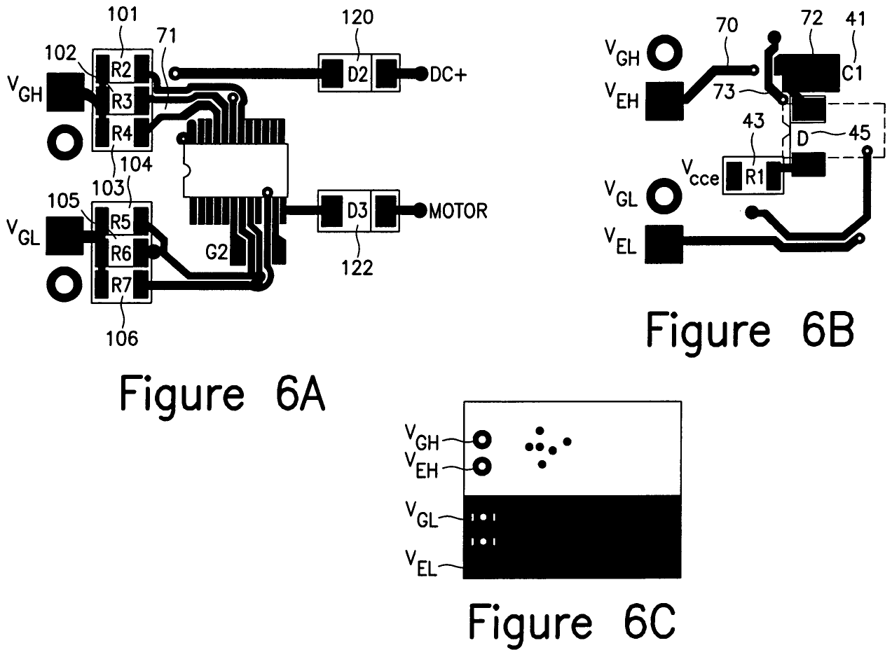

FIGS. 6A-6C are examples of three possible contact pattern layers that maybe used to couple embedded passive electronic components such as resistors 43 and 101-106, diodes 45, 120, 122 and capacitor 41. For example, the process described in connection with FIGS. 3A-3I may be used to build up embedded passive components connected by the contact pattern shown in FIGS. 6A and 6B. The contact layer of FIG. 6A is disposed above the contact layer shown in FIG. 6B, which is disposed above the contact layer shown in FIG. 6C. In one example, high side voltage V_{EH} is coupled to a first wire trace segment 70, as shown in FIG. 6B. The first wire trace segment 70 is coupled to a second wire trace segment 72 by a third wire trace segment 71, the third segment being disposed on the contact layer shown in FIG. 6A. By coupling these segments 70, 71, 72 in this manner, these wire traces 70, 71, 72 avoid making electrical contact with another wire trace segment 73, which is shown in FIG. 6B. Thus, an embedded power management control circuit 10 may be coupled to embedded passive devices by a three-dimensional network formed by coupling a plurality of contact pattern layers, each disposed at least partially above the other. In one example, stacking each of the contact layers 31, 33, 35 disposes each layer directly above the other, providing a circuit board surface no larger than that required for the active semiconductive devices that are to be mounted on the control board 14, such as a power integrated circuit 12. By limiting the area of the control board 14, valuable real estate on the surface of the motherboard (not shown) is conserved.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A peripheral electronic system for an electronic device including a motherboard, the peripheral electronic system being comprised of:
a composite structure including a plurality of individual electrically connected vertically stacked modules, at least one of the modules being comprised of a circuit board assembly including active and/or passive electronic components embedded therein with the components being electrically connected by conductive traces to provide desired operating function,
the peripheral electronic system further including an electrical connector array on an exposed surface of the composite structure adapted to provide electrical connections between the peripheral electronic system and the motherboard.

2. A peripheral electronic system according to claim 1, wherein the desired operating function is a combined power supply and power management system for the motherboard.

3. A peripheral electronic system according to claim 1, wherein the circuit board includes a plurality of laterally spaced integrated circuits.

4. A peripheral electronic system according to claim 1, wherein first and second electronic components on the boards is electrically connected by a conductive trace including first and second segments on a first contact layer and a third segment on a second vertically adjacent contact layer connected between the first and second segments.

5. A peripheral electronic system according to claim 4, wherein the first and second segments are connected to the third segment by respective openings through the second contact layer.

6. A peripheral electronic system as described in claim 4, wherein the conductive trace is formed of a metallic or a non-metallic electrically conductive material.

7. A peripheral electronic system according to claim 4, including a further conductive trace embedded in the first circuit board, wherein:
at least a portion of the further conductive trace is disposed between the first and second electronic components; and
the further conductive trace is crossed by the third segment but is electrically isolated therefrom by virtue of the location of the third segment on the second vertically spaced contact layer.

8. A peripheral electronic system according to claim 7, wherein electronic components of the vertically spaced modules are connected together by respective ball grid arrays, and the electrical connector array is a further ball grid array.

9. A peripheral electronic system according to claim 4, wherein electronic components of the vertically spaced modules are connected together by respective ball grid arrays and solderable contacts, and the electrical connector array is a further ball grid array.

10. A peripheral electronic system according to claim 4, wherein electronic components of the vertically spaced modules are connected together by respective solderable metallized contacts and conductive traces, and the electrical connector array is comprised of solderable metallized contacts and conductive traces.

11. A peripheral electronic system according to claim 4, wherein electronic components of the vertically spaced modules are connected together by an array of conductive and non-conductive interconnects.

12. A peripheral electronic system according to claim 9, further including an integrated circuit embedded in the circuit board, the embedded integrated circuit being connected to the circuit board by a flip chip structure and solderable contacts..

13. A peripheral electronic system according to claim 9, further including an integrated circuit embedded in the circuit board, the embedded integrated circuit being connected to the circuit board by an array of conductive and non-conductive interconnects.

14. A peripheral electronic system according to claim 4, further including an integrated circuit embedded in the circuit board, wherein:
the embedded integrated circuit is connected to the circuit board by a flip chip structure and solderable contacts, and the circuit board is connected to an adjacent module in the vertical stack by a ball grid array and solderable contacts.

15. A peripheral electronic system according to claim 4, further including an integrated circuit embedded in the circuit board, wherein:
the embedded integrated circuit is connected to the circuit board by a flip chip structure and the circuit board is connected to an adjacent module in the vertical stack by solderable metallized contacts and conductive traces.

16. A peripheral electronic system according to claim 4, further including an integrated circuit embedded in the circuit board, wherein:
the embedded integrated circuit is connected to the circuit board, and the circuit board is connected to an adjacent module in the vertical stack by respective arrays of conductive and non-conductive interconnects.

17. A peripheral electronic system according to claim 1, wherein the vertically stacked modules are connected together by respective ball grid arrays and solderable contacts, and the electrical connector array is a further ball grid array.

18. A peripheral electronic system according to claim 1, wherein the vertically stacked modules are connected together by respective solderable metallized contacts and conductive traces, and the electrical connector array is comprised of solderable metallized contacts and conductive traces

19. A peripheral electronic system according to claim 1, wherein the vertically stacked modules are connected together by respective arrays of conductive and non-conductive interconnects, and the electrical connector array is an array of conductive and non-conductive interconnects.

20. A peripheral electronic system according to claim 1, further including an integrated circuit embedded in the circuit board, the embedded integrated circuit being connected to the circuit board by a flip chip structure and the circuit board being connected to an adjacent module in the vertical stack by a ball grid array.

21. A peripheral electronic system according to claim 1, further including an integrated circuit embedded in the circuit board, the embedded integrated circuit being connected to the circuit board by a flip chip structure and the circuit board being connected to an adjacent module in the vertical stack by a solderable contact structure.

22. A peripheral electronic system according to claim 1, further including a heat sink attached to the stacked modules.

23. A peripheral electronic system according to claim 1, wherein the circuit board includes a plurality of laterally spaced embedded integrated circuits

24. A peripheral electronic system according to claim 1, wherein the circuit board includes at least one embedded integrated circuit and a laterally spaced embedded transistor.

25. A peripheral electronic system according to claim 1, wherein at least one pair of electronic components electrically connected together by conductive traces plated directly onto the components.

26. A peripheral electronic system according to claim 1, wherein at least one of an IC, a power device, an active component other than a power device, and a passive device is mounted on the top of the substrate, and at least one of an IC, a power device, an active component other than a power device, and a passive device is embedded in the substrate structure.

27. An electronic device including a peripheral electronic system according to claim 1, and further including a motherboard, wherein the motherboard and the peripheral electronic system are connected together electrically by the electrical connector array.

28. A method of assembling a peripheral electronic system for an electronic device including a motherboard and the peripheral electronic system, the method comprising the steps of:
fabricating a first module in the form of a circuit board including a first group of electronic components embedded therein and electrically interconnected by embedded conductive traces to provide a first part of the functionality of the peripheral electronic system, then encapsulating the circuit board while leaving an exposed electrical connecting structure;
fabricating a second module including a second group of electronic components embedded therein which are electrically connected to provide the second part of the functionality of the peripheral electronic system, then encapsulating the second module while leaving an exposed second electrical connecting structure;
assembling the first and second encapsulated module in a vertical stack with the first sand second electrical connection structures providing electrical connection between the first and second modules; and
providing a third electrical connecting structure on an exposed surface of one of the vertically stacked modules, the third electrical connecting structure being adapted for electrically connecting the assembled modules to the motherboard.

29. A method assembling an electronic device including a motherboard and a peripheral electronic system, the method comprising the steps of:
assembling the peripheral electronic subsystem according to the method of claim 28; and
electrically attaching the third connecting structure on the peripheral electronic system to the motherboard.
